(19) United States
(12) Patent Application Publication
(10) Pub. No.: US 2009/0224246 A1
(43) Pub. Date: Sep. 10, 2009

(54) THIN FILM TRANSISTOR, DISPLAY DEVICE USING THE SAME, AND METHOD OF MANUFACTURING THE SAME

(76) Inventors: Tae-Hyung Hwang, Seoul (KR); Hyung-II Jeon, Incheon-si (KR); Seok-Joon Hong, Seoul (KR)

Correspondence Address: Haynes and Boone, LLP;IP Section, 2323 Victory Avenue, SUITE 700, Dallas, TX, 75219, US

(21) Appl. No.: 12/345,410

(22) Filed: Dec. 29, 2008

(30) Foreign Application Priority Data
Mar. 5, 2008 (KR) 10-2008-0020392

(51) Int. Cl. H01L 29/78; H01L 33/00; H01L 21/02

(52) U.S. Cl. 257/59; 438/29; 438/151; 257/E21.002; 257/E33.055; 257/E29.273

(57) ABSTRACT

A thin film transistor (TFT) substrate, a display device having the same, and a method for manufacturing the same are disclosed. The TFT substrate includes: a substrate; a TFT formed on the substrate, the TFT including a gate electrode, a semiconductor layer, a source electrode, and a drain electrode; and a light blocking film formed on the TFT and overlapping with the semiconductor layer.

### CROSS-REFERENCE TO RELATED APPLICATION

This application claims priority to and the benefit of Korean Patent Application No. 10-2008-0020392 filed in the Korean Intellectual Property Office on Mar. 5, 2008, the entire contents of which are incorporated herein by reference.

### BACKGROUND OF THE INVENTION

(a) Field of the Invention

The present invention relates to a display device and a method of manufacturing the display device.

(b) Description of the Related Art

There are various types of display devices. Recently, a display device that can display images with relatively small driving power by using electrophoresis has been developed.

A display device using electrophoresis includes a pair of electrodes that generate electric fields and electrophoretic particles disposed between the pair of electrodes. In the display device, a potential difference of voltages applied to the pair of electrodes is controlled to operate the electrophoretic particles. Namely, the display device displays an image according to the electrostatic movement of particles floating in space.

A display device using electrophoresis is basically a reflective display device that displays images by allowing ambient light to be reflected by the electrophoretic particles. Ambient light is mostly reflected by the electrophoretic particles, and in this case, a portion of the light is substantially transmitted through the electrophoretic particles.

The transmitted light causes degradation of the characteristics of the thin film transistors (TFTs) used as switching elements. This is because external light is introduced into a semiconductor layer of the TFT which in turn degrades the semiconductor layer.

The above information disclosed in this Background section is only for enhancing the understanding of the background of the invention and therefore it may contain information that does not constitute the prior art that is already known in this country to a person of ordinary skill in the art.

### SUMMARY OF THE INVENTION

[Narrative version of the claim language: go back and edit once the claims have been edited] An exemplary embodiment of the present invention provides a thin film transistor (TFT) substrate including: a substrate; a thin film transistor (TFT) formed on the substrate, the TFT having a gate electrode, a semiconductor layer, a source electrode, and a drain electrode; a pixel electrode formed on the TFT and electrically connected with the drain electrode; and a light blocking film formed on the pixel electrode and overlapping with the semiconductor layer.

The light blocking film may include a material that blocks light of a wavelength range that degrades the semiconductor layer of the TFT.

The light blocking film may block light of a wavelength within the range of about 100 nm to 600 nm.

The light blocking film may include amorphous silicon.

The light blocking film may include a photosensitive polymer material (photoresist).

The light blocking film and the pixel electrode may have substantially the same shape, in plan view.

Another embodiment of the present invention provides a method for fabricating a thin film transistor substrate, including: forming a thin film transistor (TFT) including a gate electrode, a semiconductor layer, a source electrode, and a gate electrode on a substrate; forming a pixel electrode electrically connected with the drain electrode of the TFT; and forming a light blocking film on the pixel electrode such that the light blocking film overlaps with the semiconductor layer.

The light blocking film may include a material that blocks light of a wavelength range that degrades the semiconductor layer of the TFT.

The light blocking film may include amorphous silicon.

The light blocking film may include a photosensitive polymer material.

Yet another embodiment of the present invention provides a method for fabricating a thin film transistor, including: forming a thin film transistor (TFT) including a semiconductor layer on a substrate; forming a passivation layer on the TFT; forming a conductive layer on the passivation layer; depositing a photosensitive polymer material on the conductive layer; etching the photosensitive polymer material such that it overlaps with the semiconductor layer to form a photosensitive polymer pattern; and etching the conductive layer by using the photosensitive polymer pattern to form a pixel electrode.

Still another embodiment of the present invention provides a display device including a thin film transistor substrate and an electrophoretic display unit. The thin film transistor (TFT) substrate may include: a substrate; a TFT including a gate electrode, a semiconductor layer, a source electrode, and a drain electrode, and that is formed on the substrate; a pixel electrode formed on the TFT and electrically connected with the drain electrode; and a light blocking film formed on the pixel electrode and overlapping with the semiconductor layer.

The light blocking film may include a material that blocks light of a wavelength range that degrades the semiconductor layer of the TFT.

The light blocking film may block light of a wavelength within the range of about 100 nm to 600 nm.

The light blocking film may include amorphous silicon.

The light blocking film may include a photosensitive polymer material.

The light blocking film and the pixel electrode may have substantially the same shape, in plan view.

The electrophoretic display unit may include: an electrophoretic display layer formed on the light blocking film; a transparent electrode formed on the electrophoretic display layer; and a transparent base film disposed on the transparent electrode, wherein the electrophoretic display layer includes electrophoretic particles with charges.

The display device may further include an adhesive layer disposed between the light blocking film and the electrophoretic display unit.

Another embodiment of the present invention provides a method for fabricating a display device, including: forming a thin film transistor (TFT) on a substrate, the TFT including a gate electrode, a semiconductor layer, a source electrode, and a drain electrode; forming a pixel electrode electrically connected with the drain electrode of the TFT; forming a light blocking film on the pixel electrode such that the light blocking film overlaps with the semiconductor layer; preparing an electrophoretic display unit; and disposing the electrophoretic display unit on the light blocking film.

The light blocking film may include a material that blocks light of a wavelength range that degrades the semiconductor layer of the TFT.

The light blocking film may be made to include amorphous silicon.

The light blocking film may include a photosensitive polymer material.

The electrophoretic display unit may include: an electrophoretic display layer formed on the light blocking film; a transparent electrode formed on the electrophoretic display layer; and a transparent base film disposed on the transparent electrode, wherein the electrophoretic display layer may include electrophoretic particles with electric charges.

The fabricating method may further include disposing an adhesive layer between the light blocking film and the electrophoretic display unit.

### BRIEF DESCRIPTION OF THE DRAWINGS

FIG. 1 is a layout view of a thin film transistor (TFT) substrate according to a first exemplary embodiment of the present invention.

FIG. 2 is a cross-sectional view of a display device having the TFT substrate in FIG. 1.

FIG. 3 is a graph showing transmittance of amorphous silicon and a photosensitive polymer material.

FIG. 4 is a schematic view showing a driving principle of the display device in FIG. 1.

FIGS. 5 to 7 are cross-sectional views sequentially showing a method for fabricating the display device in FIG. 1.

FIG. 8 is a cross-sectional view of a display device according to a second exemplary embodiment of the present invention.

FIG. 9 is a cross-sectional view showing a method for fabricating the display device in FIG. 8.

FIG. 10 is a cross-sectional view of a display device according to a third exemplary embodiment of the present invention.

### DESCRIPTION OF REFERENCE NUMERALS INDICATING PRIMARY ELEMENTS IN THE DRAWINGS

110: substrate member

124: gate electrode

130: gate insulating layer

140: semiconductor layer

165: source electrode

166: drain electrode

170: passivation layer

180: pixel electrode

191: light blocking film

200: electrophoretic display unit

210: base film

220: transparent electrode

250: electrophoretic display layer

270: electrophoretic passivation layer

290: adhesive layer

2511: microcapsule

2512: binder

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the accompanying drawings, a display using an amorphous silicon (a-Si) thin film transistor (TFT) formed through a masking process that uses five sheets of masks is illustrated.

In order to clarify the present invention, parts that are not connected with the description will be omitted, and the same elements or equivalents are referred to by the same reference numerals throughout the specification.

In describing the exemplary embodiments of the present invention, the same reference numerals are used for elements having the same constructions and representatively described in a first exemplary embodiment of the present invention, and in other remaining exemplary embodiments of the present invention, only different constructions from those of the first exemplary embodiment will be described.

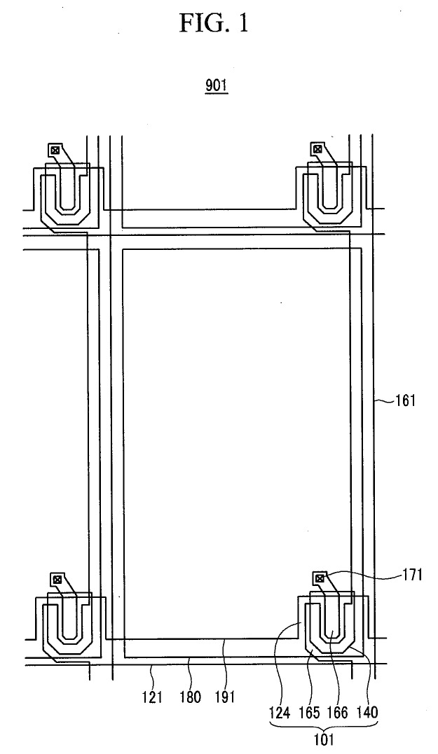

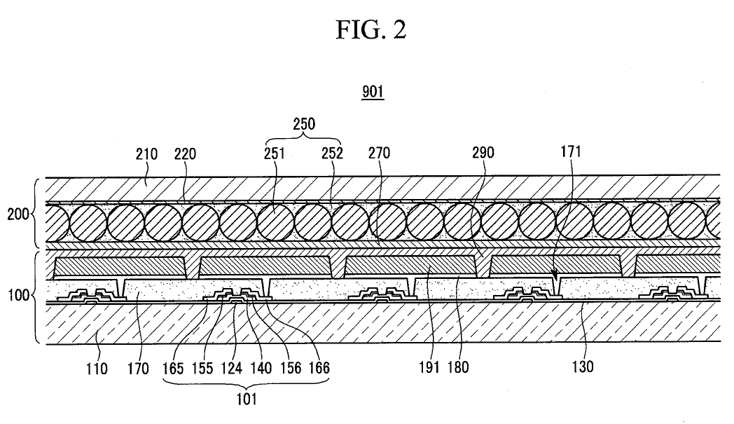

A TFT substrate 100 and a display device 901 having the same according to a first exemplary embodiment of the present invention will now be described with reference to FIGS. 1 and 2.

With reference to FIG. 2, the display device 901 includes the TFT substrate 100 and an electrophoretic display unit 200. The display device 901 further includes an adhesive layer 290 disposed between the TFT substrate 100 and the electrophoretic display unit 200.

The TFT substrate 100 includes a substrate 110, a TFT 101 formed on the substrate 110, a pixel electrode 180 formed on the TFT 101, and a light blocking film 191 formed on the pixel electrode 180 and covering the TFT 101.

The TFT 101 includes a gate electrode 124, a semiconductor layer 140, a source electrode 165, ohmic contact layers 155 and 156, and a drain electrode 166, wherein the drain electrode 166 is electrically connected with the pixel electrode 180. The TFT 101, which is a switching element, forms an electric field between the pixel electrode 180 and a transparent electrode 220 of the electrophoretic display unit 200 (described later).

The light blocking film 191 is formed to substantially overlap with the semiconductor layer 140 of the TFT 101. Thus, the light blocking film 191 suppresses introduction of light to the semiconductor layer 140 of the TFT 101. The light blocking film 191 is made of a material that blocks light of a wavelength band that degrades the semiconductor layer 140 of the TFT 101. In particular, the light blocking film 191 may have an effect of blocking light of a wavelength ranging from about 100 nm to 600 nm.

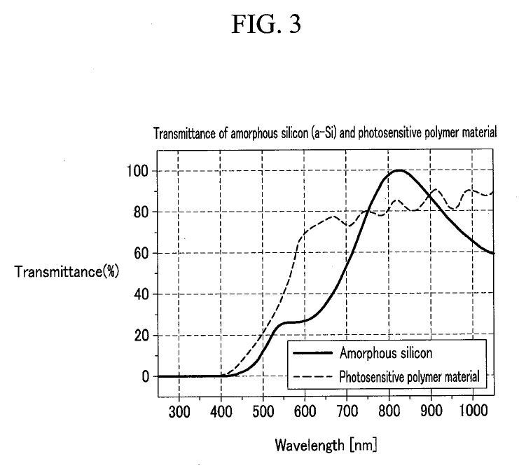

FIG. 3 is a graph showing transmittance as a function of wavelength. The transmittance is of light passing through amorphous silicon commonly used as a material of the semiconductor layer 140 (solid line) and a photosensitive polymer material (photoresist: PR) (broken line). Namely, FIG. 3 shows the transmittance of different wavelengths of bands of light that pass through the amorphous silicon and the photosensitive polymer material. As shown in FIG. 3, it is noted that amorphous silicon does not allow light of wavelength bands close to ultraviolet rays to be easily transmitted. The photosensitive polymer material is similar to the amorphous silicon in that both materials allow little light to be transmitted in the lower-wavelength region.

The light of the wavelength bands that fail to be transmitted through amorphous silicon is absorbed by amorphous silicon and changed into heat energy. This means that the light of the wavelength bands that fail to be transmitted through amorphous silicon may react on the semiconductor layer 140 to degrade the semiconductor layer 140. Thus, the light blocking film 191 should block the light of the wavelength bands that cannot transmit through the amorphous silicon.

However, the present invention is not limited thereto. Thus, if the semiconductor layer 140 is made of a different material that is not amorphous silicon, the light blocking film 191 must also block light of the wavelength bands that react on the substance used as the material of the semiconductor layer 140.

In the first exemplary embodiment of the present invention, the light blocking film 191 is made of a photosensitive polymer material (photoresist). As mentioned above with reference to FIG. 3, the photosensitive polymer material does not transmit light of the wavelength bands that do not transmit through amorphous silicon. Namely, the light blocking film 191 made of photosensitive polymer material can block light that fails to transmit through the semiconductor layer 140 made of amorphous silicon and that thus degrades the semiconductor layer 140, to a degree. Accordingly, the light blocking film 191 made of photosensitive polymer material can block light of the wavelength bands that would react on the semiconductor layer 140 to degrade the semiconductor layer 140.

In addition, the light blocking film 191 made of photosensitive polymer material may have the same shape, in plan view, as that of the pixel electrode 180. In this case, the pixel electrode 180 is formed to cover the semiconductor layer 140 of the TFT 101 together with the light blocking film 191 made of photosensitive polymer material.

With reference to FIG. 2, the electrophoretic display unit 200 includes a base film 210, a transparent electrode 220, the electrophoretic display layer 250, and an electrophoretic passivation layer 270. The electrophoretic display layer 250 includes electrophoretic particles having electrical charges.

The structure of the display device 901 will now be described based on the stacking order.

Gate wiring including a plurality of gate lines 121 and gate electrodes 124, as shown in FIG. 1, is formed on the substrate 110, as shown in FIG. 2. Although not shown, the gate wiring may further include a plurality of first storage electrodes. Here, the substrate 110 may be formed as an insulation substrate made of glass, quartz, ceramic, plastic, or the like. If the substrate 110 is made of a material with flexibility like plastic, the usability of the display device 901 can be enhanced because the utilization range of the display device 901 can be extended. In particular, because the electrophoretic display unit 200 has flexibility, if the substrate 110 is also made of a flexible material, the display device 901 would be formed to be flexible overall, so its usability would be increased.

In addition, the substrate 110 may not necessarily need to be made of a transparent material. For instance, an insulation-processed metal plate may be used as the substrate 110.

The gate wiring including the gate electrodes 124 is made of metals such as Al, Ag, Cr, Ti, Ta, Mo, etc., or their alloys. In FIG. 1, the gate wiring is illustrated as a single layer, but the gate wiring may be formed as a multi-layer including a metal layer of Cr, Mo, Ti, Ta, or their alloys having good physical and chemical characteristics, and an Al-based or Ag-based metal layer having low resistivity.

A gate insulating layer 130 made of silicon nitride (SiNx), etc., is formed on the gate wiring.

On the gate insulating layer 130, there are data wiring formed, the data wiring including a plurality of source electrodes 165 each having at least one region overlapping with the gate electrodes 124, a plurality of drain electrodes 166 disposed to be separated from the source electrodes 165 and each having at least one region overlapping with the gate electrodes 124, and a plurality of data lines 161 crossing the gate lines 121 and connected with the source electrodes 165. Although not shown, the data wiring may further include a plurality of second storage electrode lines overlapping with the first storage electrodes.

Like the gate wiring, the data wiring may also be made of a conductive material such as chromium (Cr), molybdenum (Mo), aluminum (Al), or their alloys, and may be formed as a single layer or a multi-layer.

The semiconductor layer 140 is formed on the gate electrode 124, contacting the source electrode 165 and the drain electrode 166. Here, the gate electrode 124, the source electrode 165, and the drain electrode 166 are three electrodes of the TFT 101. If light is introduced into the semiconductor layer 140, the characteristics of the TFT 101 deteriorate. Here, the TFT 101 is not limited to having the structure as shown in the accompanying drawings, and may have various other known structures within the scope in which a person skilled in the art may easily change.

Ohmic contact layers 155 and 156 are formed between the semiconductor layer 140 and the source and drain electrodes 165 and 166 in order to reduce contact resistance therebetween. The ohmic contact layers 155 and 156 are made of silicide, amorphous silicon, or the like, in which n-type impurities are doped in a high density.

The passivation layer 170, which is made of an inorganic insulating material such as silicon nitride, silicon oxide, etc., or an insulating material with a low dielectric constant (k) such as a-Si:C:O, a-Si:O:F, etc., formed through plasma enhanced chemical vapor deposition (PECVD), is formed on the data wiring.

The plurality of pixel electrodes 180 are formed on the passivation layer 170. The pixel electrodes 180 may be made by using a transparent conductor such as indium tin oxide (ITO) or indium zinc oxide (IZO), etc., or an opaque conductor such as aluminum (Al).

The passivation layer 170 includes a plurality of contact holes 171 exposing portions of the drain electrode 166. The pixel electrodes 180 and the drain electrodes 166 are electrically connected via the contact holes 171.

The light blocking films 191 are formed on the pixel electrodes 180. Here, the light blocking films 191 are made of a photosensitive polymer material (photoresist) including a component that can block light of wavelength bands that react with the semiconductor layer 140 of the TFTs 101.

The light blocking film 191 made of photosensitive polymer material has the same shape, in plan view, as that of the pixel electrode 180, and is positioned on the semiconductor layer 140 of the TFT 101 to block light of wavelength bands reacting with the semiconductor layer 140.

The adhesive layer 290 is formed on the light blocking films 191. The electrophoretic passivation layer 270, the electrophoretic display layer 250, the transparent electrode 220, and the base film 210 are sequentially formed on the adhesive layer 290. That is, the adhesive layer 290 bonds the electrophoretic display unit 200 on the light blocking films 191. In general, the electrophoretic display unit 200 is separately formed and then disposed to be bonded on the light blocking films 191. At this time, the electrophoretic display layer 250 is disposed to be positioned between the pixel electrodes 180 and the transparent electrode 220. With such a structure, the electrophoretic display layer 250 displays an image according to an electric field formed between the pixel electrodes 180 and the transparent electrode 220.

The adhesive layer 290 may be made of a water soluble resin such as a polyester-based resin, an acryl-based resin, an epoxy-based resin, a urethane-based resin, an oxazoline-based resin, a PVP(polyvinylpyrrolidone)-based resin, a polyoxyalkylene-based resin, or a cellulose-based resin, or an emulsion-based resin. The adhesive layer 290 may be coated on the light blocking films 191 according to various known methods.

The electrophoretic passivation layer 270 may be disposed on the adhesive layer 290. The electrophoretic passivation layer 270 protects the electrophoretic display layer 250 such that the electrophoretic display layer 250 cannot be separated from the base film 210, or damaged. The electrophoretic passivation layer 270 may be variably made of an organic material or an inorganic material. Also, the electrophoretic passivation layer 270 may be made of a polymer material. Then, because the electrophoretic passivation layer 270 has viscoelasticity, it can be advantageous to flexibly form the electrophoretic display unit 200.

However, the adhesive layer 290 and the electrophoretic passivation layer 270 are not essential elements and may be omitted. Namely, the electrophoretic display layer 250 may be directly formed on the light blocking films 191, on which the transparent electrode 220 and the base film 200 may be then sequentially disposed.

The electrophoretic display layer 250 may be formed on the electrophoretic passivation layer 270. The electrophoretic display layer 250 includes a binder 252 and electrophoretic microcapsules 251 mixed in the binder 252. The electrophoretic display layer 250 substantially displays an image by electrophoresis generated by the microcapsules 251.

The binder 252 serves to adhere the microcapsules 251 onto the transparent electrode 220. Further, the binder 252 may serve to protect the microcapsules 251 according to the circumstances. Various organic binders may be used as the binder 252. The binder 252 may also have sufficient adhesive power to allow the electrophoretic passivation layer 270 to be bonded to the electrophoretic display layer 250.

The microcapsules 251 each includes a capsule shell, electrophoretic particles and a dispersion medium included in the capsule shell. As the electrophoretic particles of the microcapsules 251 operate in the dispersion medium according to an electric field, the electrophoretic display unit 200 displays an image.

In the first exemplary embodiment of the present invention, the microcapsules 251 have a spherical shape. However, the present invention is not limited thereto, and the microcapsules 251 may have various other shapes such as a cylindrical shape, a hexahedral shape, etc.

The microcapsules 251 have an average diameter within the range of about 10 μm to 150 μm. If the average diameter of the microcapsules 251 is smaller than 101 μm, the electrophoretic display unit 200 cannot obtain the sufficient density required to display an image. If the average diameter of the microcapsules 251 is greater than 150 μm, the microcapsules 251 cannot have sufficient mechanical strength, possibly causing a problem in which the microcapsules 251 are broken.

The electrophoretic particles refer to solid particles that have positive or negative charges to substantially operate in the dispersion medium in response to an electric field. The electrophoretic particles may have an average diameter within the range of 0.1 μm to 5 μm. If the size of the electrophoretic particles is smaller than 0.1 μm, sufficient chromaticity cannot be obtained and the contrast would be degraded to result in the display of an indistinct and dim image. If the size of the electrophoretic particles is greater than 5 μm, the electrophoretic particles cannot move sufficiently fast which in turn degrades the response speed.

A known dispersion medium may be used as the dispersion medium without being limited, and an organic solvent is preferably used.

The transparent electrode 220 may be formed on the electrophoretic display layer 250. The transparent electrode 220 may be made of indium tin oxide (ITO), indium zinc oxide (IZO), an inorganic conductive material such as metal particles, a metal ultra-thin film, etc., or an organic conductive material such as polyacetylene, polyaniline, polypyrole, polyethylenedioxythiophene, polythiophene, etc.

The base film 210 is disposed on the transparent electrode 220. The base film 210 is made of a transparent plastic with good light transmittance. Specifically, the plastic used as the material of the base film 210 may include an acrylic resin, a polyester-based resin, a polyolefin-based resin, a polycarbonate-based resin, a polyimide-based resin, or the like. Among them, the polyester-based resin is preferably used, and polyethyleneterephthalate (PET) with good transmittance, heat resistance, rigidity, and electrical properties is more preferably used.

The electrophoretic display unit 200 may have a thickness within the range of about 20 μm to about 200 μm. If the thickness of the electrophoretic display unit 200 is smaller than 20 μm, the electrophoretic display unit 200 would be easily rumpled when attached on the light blocking films 191. If the thickness of the electrophoretic display unit 200 is greater than 200 μm, it would be difficult to roll the electrophoretic display unit 200 so as to be carried or attach the electrophoretic display unit 200 onto the light blocking films 191.

Generally, the light blocking films 191 made of photosensitive polymer material have a thickness of substantially 1 μm. Because the electrophoretic display unit 200 has a thickness within the range of about 20 μm to about 200 μm, there is no substantial influence of the light blocking films 191 employed for the display device 901 on the behavior of the electrophoretic particles.

With such a configuration, the degradation of the semiconductor layer 140 of the TFTs 101 by external light can be effectively suppressed. Accordingly, the overall durability of the display device 901 can be improved.

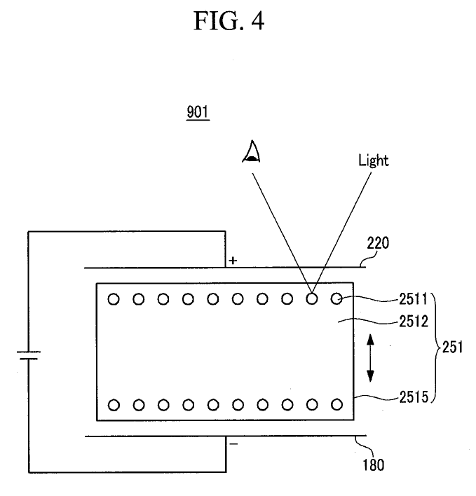

A driving principle of the display device 901 using electrophoresis will now be described in detail with reference to FIG. 4.

As shown in FIG. 4, the display device 901 includes a pair of electrodes 180 and 220 to form an electric field. One of the pair of electrodes is the pixel electrode 180, and the other is the transparent electrode (common electrode) 220 to which a common voltage is applied. A potential difference between the pixel electrode 180 and the transparent electrode 220 is formed according to a voltage applied to the pixel electrode 180 through the TFTs 101 (in FIG. 2), which are switching elements.

The electrophoretic microcapsules 251 are disposed between the pixel electrode 180 and the common electrode 220. Each microcapsule 251 includes a capsule shell 2515, and electrophoretic particles 2511 and a dispersion medium 2512 included in the capsule shell 2515. The electrophoretic particles 2511 are positive or negative polarity.

When a voltage is applied to the facing pixel electrode 180 and transparent electrode 220 to form a potential difference (+, −) between the electrodes 180 and 220, the electrophoretic particles 2511 move toward one of the electrodes 180 and 220 of the opposite polarity.

Then, a user perceives light that is reflected from the electrophoretic particles 2511 after the light is made incident from the exterior. If the electrophoretic particles 2511 move upward, toward the user, the user can recognize the intense color of the electrophoretic particles 2511. If the electrophoretic particles 2511 move downward a weak color will be viewed by the user.

The movement of the electrophoretic particles 2511 is caused by electrophoresis which refers to a phenomenon in which particles assuming a surface charge move toward electrodes assuming the opposite charge in the electric field.

Based on such a principle, the display device 901 using electrophoresis displays images.

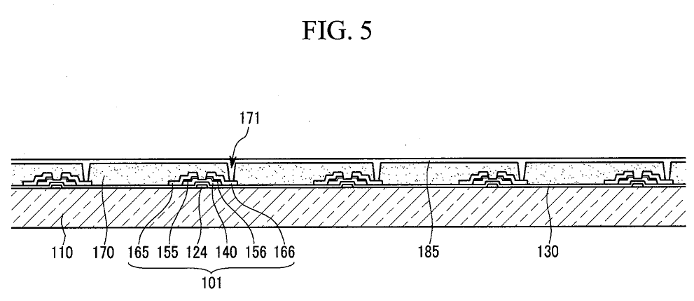

The fabrication process of the display device 901 according to the first exemplary embodiment of the present invention will now be described with reference to FIGS. 5 to 7.

First, as shown in FIG. 5, the TFTs 101 each including the gate electrode 124, the semiconductor layer 140, the source electrode 165, the ohmic contact layers 155 and 156, and the drain electrode 166 are formed on the substrate 110. Here, the TFT 101 is not limited to having the structure shown in the accompanying drawings, and may have various other known structures within the scope in which a person skilled in the art may easily change.

The passivation layer 170 covering the TFTs 101 is then formed. The passivation layer 170 includes contact holes 171 exposing portions of the drain electrode 165 of the TFTs 101.

Next, a conductive layer 185 is formed on the passivation layer 170. The conductive layer 185 may be made of a transparent conductive material such as ITO or IZO, or an opaque reflective material such as a metal film.

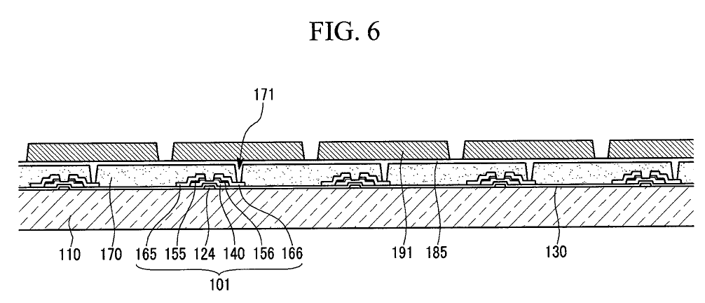

Thereafter, as shown in FIG. 6, photosensitive polymer patterns covering the TFTs 101 is formed on the conductive layer 185. A photosensitive polymer pattern (photoresist pattern) may be formed by coating a photosensitive polymer material and then performing photolithography using a mask thereon. The photosensitive polymer material used as the material of the photosensitive polymer pattern includes a component that can block light of a wavelength band reacting with the semiconductor layer 140 of the TFT 101. The photosensitive polymer pattern becomes the light blocking film 191.

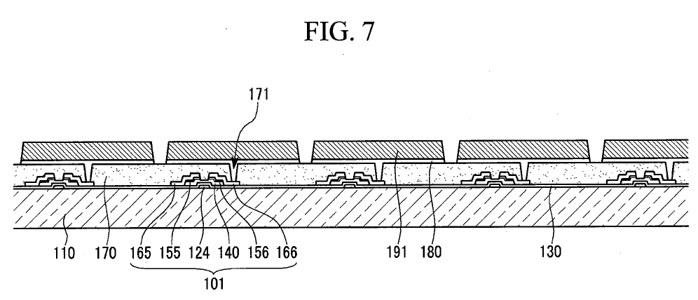

Then, as shown in FIG. 7, the conductive layer 185 is etched by using the photosensitive polymer pattern to form the pixel electrode 180, and in this case, the light blocking film 191 and the pixel electrode 190 may have substantially the same shape, in plan view. The pixel electrode 180 covers the semiconductor layer 140 of the TFT 101 together with the photosensitive polymer pattern, namely, the light blocking film 191.

As shown in FIG. 2, the adhesive layer 290 is subsequently coated on the photosensitive polymer pattern, which is the light blocking film 191, on which the electrophoretic display unit 200 is attached, to form the display device 901 as shown in FIG. 1.

According to such method for manufacturing the display device 901, the display device 901 in which the degradation of the semiconductor layer 140 of the TFT 101 by external light can be effectively suppressed can be manufactured. Thus, the display device 901 can have improved durability.

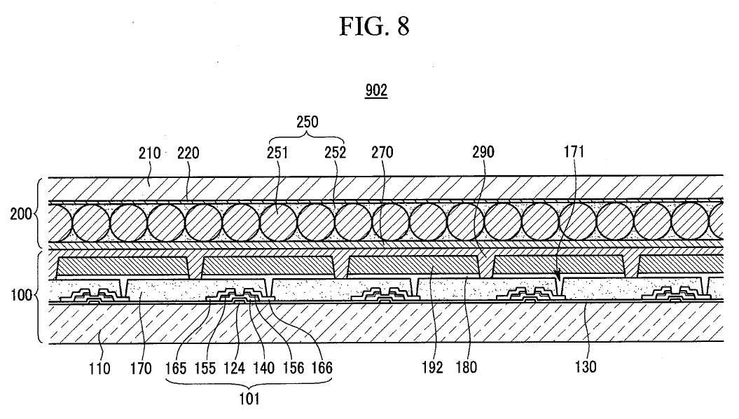

The TFT substrate 100 and a display device 902 having the same according to a second exemplary embodiment of the present invention will now be described with reference to FIG. 8.

As shown in FIG. 8, the display device 902 includes the TFT substrate 100 and the electrophoretic display unit 200. The display device 902 further includes an adhesive layer 290 disposed between a light blocking film 192 and the electrophoretic display unit 200.

The TFT substrate 100 includes the substrate 110, the TFT 101 formed on the substrate 110, and the light blocking film 192 covering the semiconductor layer 140. The TFT substrate 100 further includes the pixel electrode disposed between the light blocking film 192 and the TFT 101. Namely, the light blocking film 192 is formed on the pixel electrode 180 to cover the semiconductor layer 140 of the TFT 101. Here, the light blocking film 192 may not be formed only at positions corresponding to the pixel electrode, but may cover the TFT 101 regardless of the disposition of the pixel electrode 180.

FIG. 8 shows the case where the pixel electrode 180 covers the TFT 101 and the light blocking film 192 covers the entire surface including the upper portion of the TFT 101, but the second exemplary embodiment of the present invention is not limited thereto. Namely, the pixel electrode 180 may be designed differently, and the light blocking film 192 may only be formed on the portion that covers the semiconductor layer 140 of the TFT 101 regardless of the pixel electrode 180.

The light blocking film 192 is made of a material including amorphous silicon that is mainly used as a material for the semiconductor layer 140. Thus, the light blocking film 192 may more effectively suppress the introduction of light onto the 25 semiconductor layer 140 of the TFT 101. That is, because the light blocking film 192 is made of a component that is substantially similar to that of the semiconductor layer 140, light that may affect the semiconductor layer 140 can be effectively blocked.

Generally, the light blocking film 192 made of amorphous silicon may have a thickness even smaller than 1 μm. In comparison, the electrophoretic display unit 200 has a thickness within the range of 20 μm to 200 μm, so the light blocking film 192 added to the display device 902 cannot substantially affect the operation of the electrophoretic particles.

With such a configuration, the degradation of the semiconductor layer 140 of the TFT 101 by external light can be effectively suppressed. Thus, the overall durability of the display device can be improved.

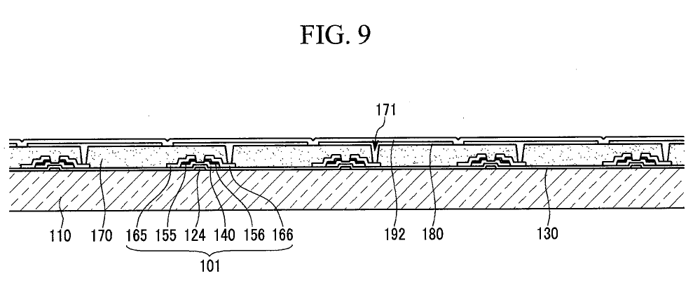

The manufacturing process of the display device 902 according to the second exemplary embodiment of the present invention will now be described with reference to FIG. 9.

The TFT 101 including the gate electrode 124, the semiconductor layer 140, the source electrode 165, the drain electrode 166, the ohmic contact layers 155 and 156, and the pixel electrode 180 electrically connected with the drain electrode 166 are formed on the substrate 110. That is, the steps of the manufacturing method leading up to the process of forming the pixel electrode 180 by using the photosensitive polymer pattern in the second exemplary embodiment of the present invention are the same as that in the method for manufacturing the display device 901 according to the first exemplary embodiment of the present invention. However, in the method for manufacturing the display device 902 according to the second exemplary embodiment of the present invention, after the pixel electrode 180 is formed, the photosensitive polymer pattern is removed.

Next, as shown in FIG. 9, the light blocking film 192 is formed with a material of amorphous silicon. The light blocking film 192 covers the semiconductor layer 140 of the TFT 101, and the amorphous silicon is commonly used as a material of the semiconductor layer 140.

As shown in FIG. 8, the adhesive layer 290 is then coated on the light blocking film 192, on which the electrophoretic display unit 200 is then attached to form the display device 902.

According to such method for manufacturing the display device 902, the display device 902 in which the degradation of the semiconductor layer 140 of the TFT 101 by external light can be effectively suppressed can be manufactured. Thus, the display device 902 can have improved durability.

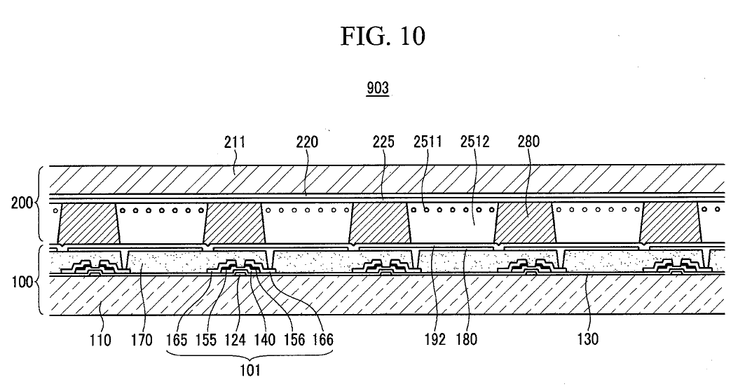

A display device 903 according to a third exemplary embodiment of the present invention will now be described with reference to FIG. 10.

As shown in FIG. 10, the display device 903 includes the TFT 100 and the electrophoretic display unit 200. In addition, the display device 903 may further include an adhesive layer (not shown in FIG. 10 but shown as adhesive layer 290 in FIG. 8) disposed between the light blocking film 192 and the electrophoretic display unit 200.

The TFT substrate 100 includes the substrate 110, the TFT 101 formed on the substrate 110, and the light blocking film 192 covering the TFT 101. Further, the TFT substrate 100 includes the pixel electrode 180 disposed between the light blocking film 192 and the TFT 101. That is, the light blocking film 192 is formed on the pixel electrode 180 and covers the semiconductor layer 140 of the TFT 101.

The electrophoretic display unit 200 of the display device 903 according to the third exemplary embodiment of the present invention is not separately formed and attached but is directly formed on the light blocking film 192.

The electrophoretic display unit 200 includes barrier rib members 280, the electrophoretic particles 2511, the dispersion medium 2512, a sealing adhesive layer 225, the transparent electrode 220, and a transparent base substrate 211. The transparent base substrate 211 may be an insulation substrate made of a material such as glass, plastic, etc., or a transparent base film.

The barrier rib members 280 are formed on the light blocking film 192 and distinguish a space above one pixel electrode 180 from that of another pixel electrode 180. Namely, the barrier rib members 280 have a receiving portion formed to receive the electrophoretic particles 2511 and the dispersion medium 2512 at every upper portion of each pixel electrode 180.

The electrophoretic particles 2511 and the dispersion medium 2512 are disposed in the receiving portion formed by the barrier rib members 280.

The sealing adhesive layer 225 is attached to the barrier rib members 280 to prevent the electrophoretic particles 236 on one pixel electrode 180 from moving onto another pixel electrode 180. The sealing adhesive layer 225 may be made of a polymer-based material.

The transparent electrode 220 (also known as the common electrode) forms an electric field together with the pixel electrode 180 to operate the electrophoretic particles 2511 disposed in the receiving portions of the barrier rib members 280.

With such a configuration, the degradation of the semiconductor layer 140 of the TFTs 101 by external light can be effectively suppressed. Thus, the overall durability of the display device 903 can be improved.

According to the present invention, the degradation of the semiconductor layers of the TFTs by external light can be effectively suppressed. Thus, the overall durability of the display device 903 can be improved.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor (TFT) substrate comprising:
a substrate;
a thin film transistor (TFT) formed on the substrate, the TFT having a gate electrode, a semiconductor layer, a source electrode, and a drain electrode;
a pixel electrode formed on the TFT and electrically connected with the drain electrode; and
a light blocking film formed on the pixel electrode and overlapping with the semiconductor layer.

2. The substrate of claim 1, wherein the light blocking film comprises a material that blocks light of a wavelength range that degrades the semiconductor layer of the TFT.

3. The substrate of claim 2, wherein the light blocking film blocks light of a wavelength within a range of about 100 nm to 600 nm.

4. The substrate of claim 1, wherein the light blocking film comprises amorphous silicon.

5. The substrate of claim 1, wherein the light blocking film comprises a photosensitive polymer material.

6. The substrate of claim 5, wherein the light blocking film and the pixel electrode have substantially the same shape, in plan view.

7. A method for fabricating a thin film transistor substrate, comprising:
forming a thin film transistor (TFT) on a substrate, the TFT comprising a gate electrode, a semiconductor layer, a source electrode, and a gate electrode;
forming a pixel electrode electrically connected with the drain electrode of the TFT; and
forming a light blocking film on the pixel electrode such that the light blocking film overlaps with the semiconductor layer.

8. The method of claim 7, wherein the light blocking film comprises a material that blocks light of a wavelength range that degrades the semiconductor layer of the TFT.

9. The method of claim 7, wherein the light blocking film comprises amorphous silicon.

10. The method of claim 7, wherein the light blocking film comprises a photosensitive polymer material.

11. A method for fabricating a thin film transistor, comprising:
forming a thin film transistor (TFT) on a substrate, the TFT comprising a semiconductor layer;
forming a passivation layer on the TFT;
forming a conductive layer on the passivation layer;
depositing a photosensitive polymer material on the conductive layer;
etching the photosensitive polymer material such that the photosensitive polymer material overlaps with the semiconductor layer to form a photosensitive polymer pattern; and
etching the conductive layer by using the photosensitive polymer pattern to form a pixel electrode.

12. A display device comprising a thin film transistor (TFT) substrate and an electrophoretic display unit, wherein the TFT substrate comprises:
a substrate;
a TFT formed on the substrate, the TFT comprising a gate electrode, a semiconductor layer, a source electrode, and a drain electrode;
a pixel electrode formed on the TFT and electrically connected with the drain electrode; and
a light blocking film formed on the pixel electrode and overlapping with the semiconductor layer.

13. The device of claim 12, wherein the light blocking film comprises a material that blocks light of a wavelength range that degrades the semiconductor layer of the TFT.

14. The device of claim 13, wherein the light blocking film blocks light of a wavelength within a range of about 100 nm to 600 nm.

15. The device of claim 12, wherein the light blocking film comprises amorphous silicon.

16. The device of claim 12, wherein the light blocking film comprises a photosensitive polymer material.

17. The device of claim 16, wherein the light blocking film and the pixel electrode have substantially the same shape, in plan view.

18. The device of claim 12, wherein the electrophoretic display unit comprises:
an electrophoretic display layer formed on the light blocking film;
a transparent electrode formed on the electrophoretic display layer; and
a transparent base film disposed on the transparent electrode,
wherein the electrophoretic display layer comprises electrophoretic particles with charges.

19. The device of claim 18, further comprising
an adhesive layer disposed between the light blocking film and the electrophoretic display unit.

20. A method for manufacturing a display device, the method comprising:
forming a thin film transistor (TFT) on a substrate, the TFT comprising a gate electrode, a semiconductor layer, a source electrode, and a drain electrode;
forming a pixel electrode electrically connected with the drain electrode of the TFT;
forming a light blocking film on the pixel electrode such that the light blocking film overlaps with the semiconductor layer;
preparing an electrophoretic display unit; and
disposing the electrophoretic display unit on the light blocking film.

21. The method of claim 20, wherein the light blocking film comprises a material that blocks light of a wavelength range that degrades the semiconductor layer of the TFT.

22. The method of claim 20, wherein the light blocking film comprises amorphous silicon.

23. The method of claim 20, wherein the light blocking film is a photosensitive polymer material.

24. The method of claim 20, wherein the electrophoretic display unit comprises:
an electrophoretic display layer formed on the light blocking film;
a transparent electrode formed on the electrophoretic display layer; and
a transparent base film disposed on the transparent electrode,
wherein the electrophoretic display layer comprises electrophoretic particles with charges.

25. The method of claim 24, further comprising
disposing an adhesive layer between the light blocking film and the electrophoretic display unit.
